(19) United States
(12) Patent Application Publication
(10) Pub. No.: US 2026/0206145 A1
(43) Pub. Date: Jul. 16, 2026

(54) POWER MODULE AND ASSEMBLY METHOD THEREFOR

(71) Applicant: MetaPWR Electronics Co., Ltd., Shanghai (CN)

(72) Inventors: Shouyu HONG, Shanghai (CN); Hongxiu LIU, Shanghai (CN); Liuzhu Li, Shanghai (CN)

(73) Assignee: MetaPWR Electronics Co., Ltd., Shanghai (CN)

(21) Appl. No.: 19/446,945

(22) Filed: Jan. 13, 2026

(30) Foreign Application Priority Data
Jan. 13, 2025 (CN) 202510048148.0
Jun. 5, 2025 (CN) 202510741128.1

(51) Int. Cl. H05K 3/3478; H05K 1/14; H05K 3/12; H05K 3/346; H05K 3/38

(52) U.S. Cl. CPC H05K 3/3478; H05K 1/144; H05K 3/1283; H05K 3/346; H05K 3/386; H05K 2201/086; H05K 2203/043

(57) ABSTRACT

The present application discloses a stacked power module. A bonding material and solder are provided between stacked layers, and the moment when the bonding material is fully cured is later than the moment when the solder begins to melt, thereby achieving the reliability of the assembly of the stacked layers, and improving the production yield of the stacked power module. On the other hand, the present application further provides an assembly mode of the stacked power module and a system board. For different pin layouts of a lower surface of the stacked power module, several different assembly modes of the stacked power module and the system board are proposed, and the reliability of the assembly process of the stacked power module and the system board is also improved.

### CROSS-REFERENCE TO RELATED APPLICATION

This application claims the priority benefit of Chinese patent application CN202510048148.0 filed on January 13, 2025 and Chinese patent application CN202510741128.1 filed on June 5, 2025. The entirety of the above-mentioned patent application is hereby incorporated by reference herein and made a part of this specification.

### BACKGROUND

### TECHNICAL FIELD

The present invention is related to a power module and assembly method therefor.

### DESCRIPTION OF RELATED ART

In recent years, with the increasing demands of various types of artificial intelligence, data processing, etc. the computing power of various types of board cards is continuously increased, and the power consumption of a computing chip is also increased year by year. At the same time, the requirements for the size of the computing power unit are getting higher and higher, and therefore, higher and higher requirements are put forward for the occupied area of the energy processing unit.

In order to reduce the footprint of the energy processing unit, the components in the energy processing unit are stacked in a vertical direction, and the vertical stacking of each component brings about two problems.

First, electrical connection between stacked layers is usually achieved by means of reflow soldering, and in order to improve the convenience of repairing during use, organic bonding is usually employed between the stacked layers (to ensure the module is kept as a whole when replacing the module). The stacked layers are usually fixed by using red glue, in order to simplify the production process, the curing process of the red glue and reflow soldering are completed synchronously, but since the red glue has been fully cured before the solder paste of the solder joints is melted, the red glue is easy to have high standoff during the curing process, resulting in solder joint voids and other soldering defects.

Secondly, since the height of a stacked module is usually high, for example, higher than 4 mm, even up to 6 mm and above, when the stacked module is welded on the system board, in the later process, the module needs to undergo reflow soldering again on the back surface of the system board. As the module is high, the weight is large, during another reflow soldering, the solder joints are easily melted so as to cause the module to fall off from the system board. At present, filling a glue at the bottom of the module is usually processed after the module is assembled; however, filling a glue at the bottom of the module requires a high level of cleanliness at the solder joints, so that the process is not only complex, but also expensive; therefore, how to bond the module and the system board by means of bonding material is another challenge.

These problems need to be solved urgently during production and use of the power module with stacked structure.

### SUMMARY

In view of the above, one of the objectives of the application is to provide a power module, comprising a substrate, an element, a solder and a bonding material, wherein the element and the substrate are stacked; the substrate and the element are fixed and electrically connected by means of the solder;

The bonding material is further provided between the substrate and the element, and the substrate and the element are fixed by means of the bonding material;

The moment when the bonding material is fully cured is later than the moment when the solder begins to melt.

Preferably, a thickness of the power module is greater than or equal to 5 mm.

Preferably, the substrate is a first substrate, the element is a magnetic core, and the power module further comprises a second substrate; the magnetic core is assembled on the second substrate; each of the first substrate and the magnetic core comprises an upper surface and a lower surface opposite to each other, and the upper surface of the first substrate and the lower surface of the magnetic core are fixed by means of the bonding material.

Preferably, the substrate is a first substrate, and the power module further comprises a second substrate; the first substrate, the element, and the second substrate are sequentially stacked; each of the first substrate, the element and the second substrate comprises an upper surface and a lower surface opposite to each other, and the upper surface of the first substrate and the lower surface of the element are fixed by means of the bonding material; the upper surface of the element and the lower surface of the second substrate are fixed by means of the bonding material.

Preferably, the power module further comprises an additional element, each of the element and the substrate comprises an upper surface and a lower surface opposite to each other, and the lower surface of the element and the upper surface of the substrate are adjacent to each other;

the additional element is disposed on the upper surface of the substrate; the substrate is fixed on and connected to the element by means of the bonding material disposed between an upper surface of the additional element and the lower surface of the element.

Preferably, the additional element is mounted to the substrate by a fixing material.

Preferably, a lower surface of the additional element is provided with a pad, and the additional element is fixed on and electrically connected to the substrate by means of the pad and the solder; the upper surface and/or the lower surface of the additional element are provided with a surface treatment area, and the surface treatment area is used for preventing the bonding material or the fixing material from flowing into the pad.

Preferably, the power module is disposed on a system board, and the power module and the system board are fixed by means of the solder and the bonding material, and electrically connected through the solder.

Preferably, there is a gap between the bonding material and the solder provided between the power module and the system board.

Preferably, the bonding material between the power module and the system board fills a gap between the solder, and the bonding material between the power module and the system board wraps around the solder.

Preferably, a lower surface of the power module is provided with a pad region, and the bonding material is disposed around the pad region.

Preferably, the bonding material between the power module and the system board is wrapped around the solder; and a gap exists between the adjacent bonding materials wrapped the solder.

Preferably, a lower surface of the power module is provided with a pad, the pad comprises a co-potential pad region, and the bonding material is disposed in the co-potential pad region.

Preferably, the substrate comprises a pad; the bonding material is doped within the solder, and the solder with doped bonding material is disposed on the pad; or the solder is disposed on the substrate first, and then the bonding material is disposed on the surface of the solder.

A power module, comprising an element, a substrate, a solder and a bonding material, the element being disposed on the substrate; the power module is arranged on a system board, the solder and the bonding material are disposed between the substrate and the system board, the substrate is fixed and electrically connected to the system board by means of the solder, and the substrate and the system board are fixed by means of the bonding material; and the moment when the bonding material is fully cured is later than the moment when the solder starts to melt.

Preferably, the element is embedded in the substrate.

Preferably, the substrate comprises an upper surface and a lower surface, the lower surface of the substrate is provided with a pad region, and the bonding material is disposed around the pad region.

An assembly method of the power module, comprising the following steps:

step 1: first disposing the solder and the bonding material on the substrate;

step 2: attaching the element to the substrate;

step 3: performing reflow soldering on an attached combination in step 2 to complete solder welding and curing of the bonding material; and in step 3, the moment at which the bonding material is fully cured is later than the moment at which the solder starts to melt.

Preferably, the substrate is a first substrate, the power module further comprises a second substrate, the element is a magnetic core, and the step 1 further comprises: assembling the magnetic core on the second substrate; and attaching other elements on an upper surface of the first substrate, and/or an upper surface and/or a lower surface of the second substrate.

Preferably, the substrate is a first substrate, the power module further comprises a second substrate, and the assembly method further comprises:

step 4: disposing the solder and the bonding material on the second substrate, and attaching the attached combination completed in step 3 with the second substrate;

step 5: performing reflow soldering on the attached combination completed in step 4, and completing solder welding and curing of the bonding material.

Preferably, the assembly method, further comprises a solder with doped bonding material, and the solder with doped bonding material is disposed on the pad; or the solder is disposed on the substrate first, and then the bonding material is disposed on the surface of the solder.

Compared with the prior art, the application has the following beneficial effects.

The present application provides a stacked power module. The bonding material is provided between stacked layers, and the moment when the bonding material is fully cured is later than the moment when the solder begins to melt; the solder joints can freely melt and collapse, thereby avoiding excessive solder joint height, achieving the reliability of assembly between the stacked layers, and improving the production yield of the stacked power modules.

The present application further provides an assembly mode between the stacked power module and the system board. For different pin layouts of the lower surface of the stacked power module, several different assembly modes are proposed, and the reliability of the assembly process of the stacked power module and the system board is also improved.

### BRIEF DESCRIPTION OF THE DRAWINGS

FIG. 1A and FIG. 1B are an embodiment of a power module.

FIG. 2A and FIG. 2B are another embodiment of a power module.

FIG. 3A to FIG. 3D are an assembly process of a power module.

FIG. 3E is surface treatment area of a power module.

FIGS. 4A to FIG. 4F are assembly embodiments of a stacked module and a system board.

FIGS. 5A and 5B are other embodiments of a stacked module.

### DESCRIPTION OF THE EMBODIMENTS

One of the cores of the present application is to provide a power module and an assembling method thereof.

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

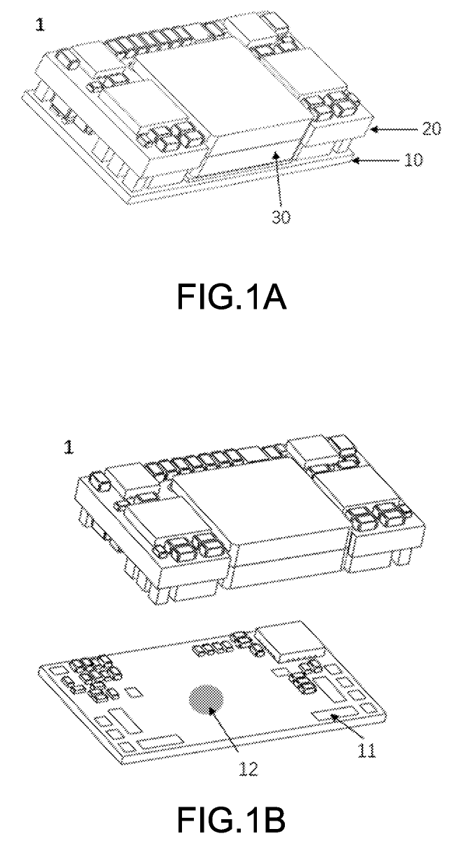

The stacked module disclosed in the present application is shown in FIG. 1A, and FIG. 1B is an exploded schematic diagram of the stacked module shown in FIG. 1A. The stacked module 1 comprises a first substrate 10, a second substrate 20, and an element 30. In the present embodiment, the element 30 is a magnetic core, and the magnetic core is assembled on the second substrate 20; the first substrate 10 and the second substrate 20 each comprise an upper surface and a lower surface opposite to each other, and each substrate can be provided with other elements. The magnetic core is fixed to the second substrate 20 by means of bonding. The magnetic core and the first substrate 10 are fixed by means of a bonding material, thereby achieving a fixed connection between the first substrate 10 and the second substrate 20. In detail, the upper surface of the first substrate 10 is provided with the bonding material 12, a pad and a solder 11, and the pad and the solder 11 are used for welding, fixing and electrically connecting to the welding surface on the lower surface of the second substrate 20, and the bonding material 12 is used for fixing with the element 30. The bonding material may be disposed on a corresponding position of the element 30, and is not limited to the illustrated position, and may be flexibly adjusted according to different process paths.

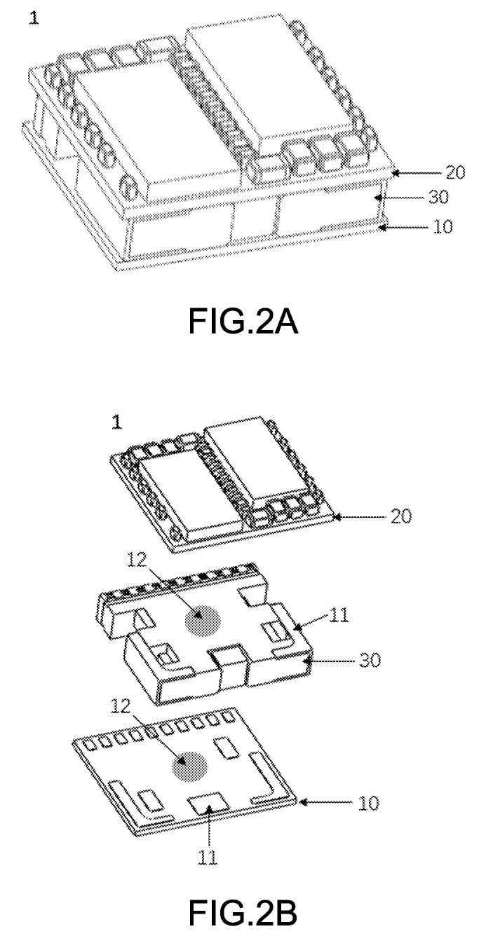

FIG. 2A is a schematic structural diagram of another stacked module, and FIG. 2B is an exploded schematic diagram of FIG. 2A. In the present embodiment, the stacked module 1 comprises a first substrate 10, a second substrate 20 and an element 30, wherein the element 30 is arranged between the first substrate 10 and the second substrate 20. Each of the first substrate 10, the second substrate 20 and the element 30 comprises an upper surface and a lower surface opposite to each other, the upper surface of the first substrate 10 being disposed adjacent to the lower surface of the element 30, the upper surface of the element 30 being disposed adjacent to the lower surface of the second substrate 20. The first substrate 10, the second substrate 20 and the element 30 are fixed and electrically connected by means of the solder provided in the pad and the solder 11; in addition, the bonding material 12 is provided on the upper surface of the first substrate 10, and the bonding material 12 is provided on the upper surface of the element 30, so as to realize the fixation between the stacked layers by means of the bonding material.

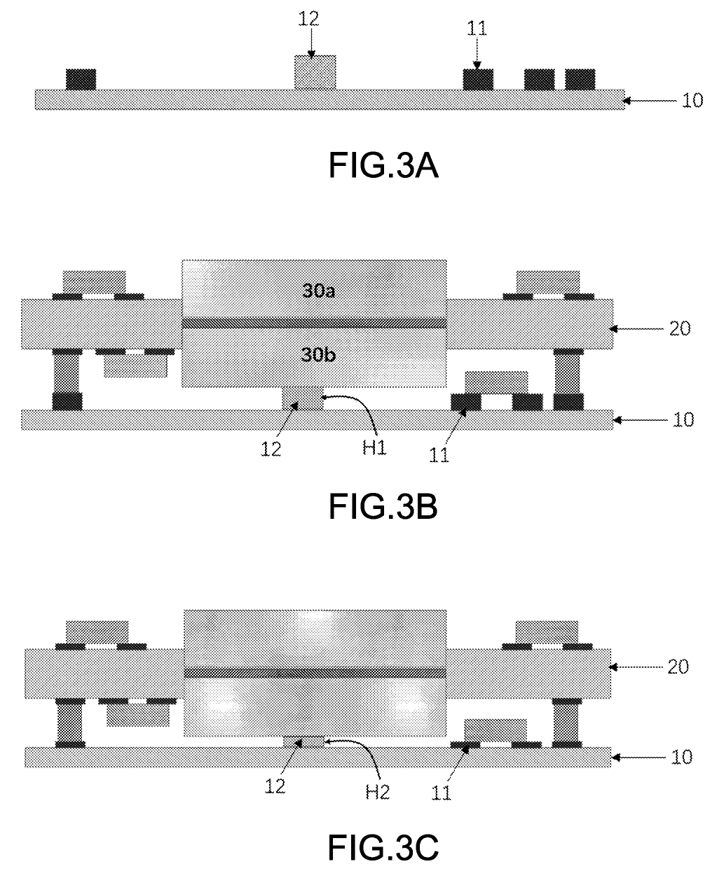

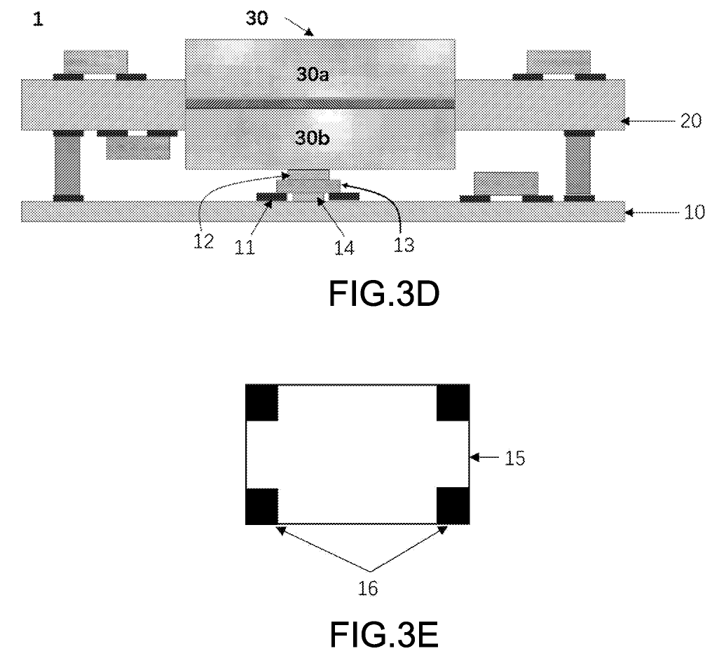

An assembly process of the stacked module 1 is also disclosed. With reference to FIG. 3A to FIG. 3D, the stacked module shown in FIG. 1A is used as an example for description:

step 1: first, the solder and the bonding material are disposed on the upper surface of the first substrate 10, as shown in FIG. 3A.

step 2: the element 30 is then attached to the first substrate 10, as shown in FIG. 3B.

step 3: then performing reflow soldering on an attaching combination in step 2 to complete solder welding and curing of the bonding material.

In the stacked module shown in FIG. 1A, the step 1 may further comprise: assembling the element 30 and the second substrate 20; furthermore, other elements are also attached to the upper surface of the first substrate 10; and other elements are also attached to the upper surface and/or the lower surface of the second substrate 20. The element 30 attached in step 2 is an element which has been assembled on the second substrate 20.

In the prior art, because during the soldering process, the solvent and the like in the solder are lost due to heating, and therefore, the volume of the solder is reduced after the solder reflow, which is generally reduced to about half of the original volume. The moment when the bonding material mentioned in the present invention is fully cured is later than the moment when the solder begins to melt, so the bonding material will collapse while the solder is melting, as the height H1 shown in FIG. 3B and the height H2 shown in FIG. 3C, wherein the height of H2 is less than the height of H1. By using the bonding material with the full cure moment later than the initiation of solder melting, the present application can effectively avoid soldering defects such as solder joint void, poor wetting and solder skip and the like due to the re-melting and collapse of the solder after the bonding material has cured, therefor the production yield is greatly improved and the cost is saved.

The stacked module shown in FIG. 2A can also adopt the above assembly process, the difference is in step 1, the assembly of the element 30 needs to be completed at the same time; and optionally, other elements can be simultaneously assembled in step 1 on the second substrate 20. In addition, the method may further include:

step 4, providing solder and the bonding material on the second substrate, and mounting the attaching combination finished in step 3 and the second substrate 20 assembled.

step 5: performing solder welding and curing of the bonding material again through reflow soldering.

The cured bonding material will not melt again upon reheating, thereby ensuring that the stacked layers, or the element and the substrate will not shift or drop from each other due to the solder re-melting during reflow.

In addition, the assembly of the element 30 and the first substrate 10 may also be as shown in FIG. 3D, the upper surface of the first substrate 10 is provided with an additional element 13; the additional element 13 is fixed and electrically connected to the first substrate 10 by means of the pad and the solder 11, and the additional element 13 is fixed to the first substrate 10 by means of the fixing material 14 arranged between the additional elements 13 and the first substrate 10. The bonding material 12 is provided between the element 30 and the additional elements 13 to realize a fixation between the first substrate 10 and the second substrate 20.

Optionally, when the additional element 13 is a metal component, the material of the metal component may be copper, iron, aluminum alloy, stainless steel, etc. wherein copper is optimal; and a welding process and a bonding process need to be completed at the same time on an upper surface and/or a lower surface of the metal component. Soldering areas such as pads 15 of the additional element 13 are usually plated with nickel-tin plating or nickel-gold plating. During the reflow soldering process of nickel-tin plating, the melting of the nickel-tin material causes a bonding failure between the additional element 13 and the first substrate 10; and during reflow soldering of nickel-gold plating, an effective chemical bond cannot be formed between the nickel-gold material and the fixing material 14 or the bonding material 12, resulting in poor adhesion. Therefore, it is necessary to perform special surface treatment on the bonding region on the upper surface or the lower surface of the metal component, and the special surface treatment techniques may be coating solder resist materials on surface, such as ink, or removing the plating layer from surface by laser, exposing the copper layer or the nickel layer. The bonding force of the fixing material or the bonding material can be increased by means of the surface treatment techniques. In addition, at least one surface treatment area 16 is provided on the upper surface or the lower surface of the metal component, as shown in FIG. 3E, the size of each surface treatment area is greater than or equal to 1 mm ×1 mm; in this way, the defects will be avoided during welding, such as the bonding material or the fixing material flowing into the pad and mixing with the solder paste, resulting in a reduced soldering reliability and affecting the adhesion of the bonding material or the fixing material.

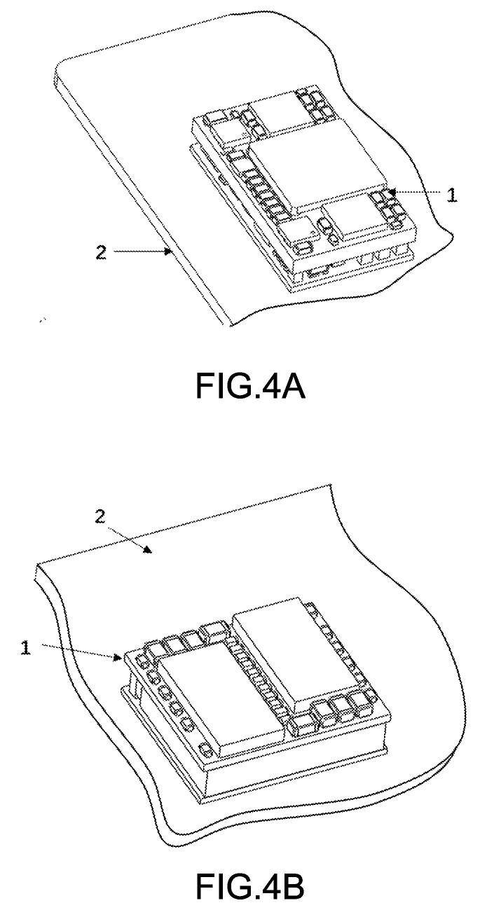

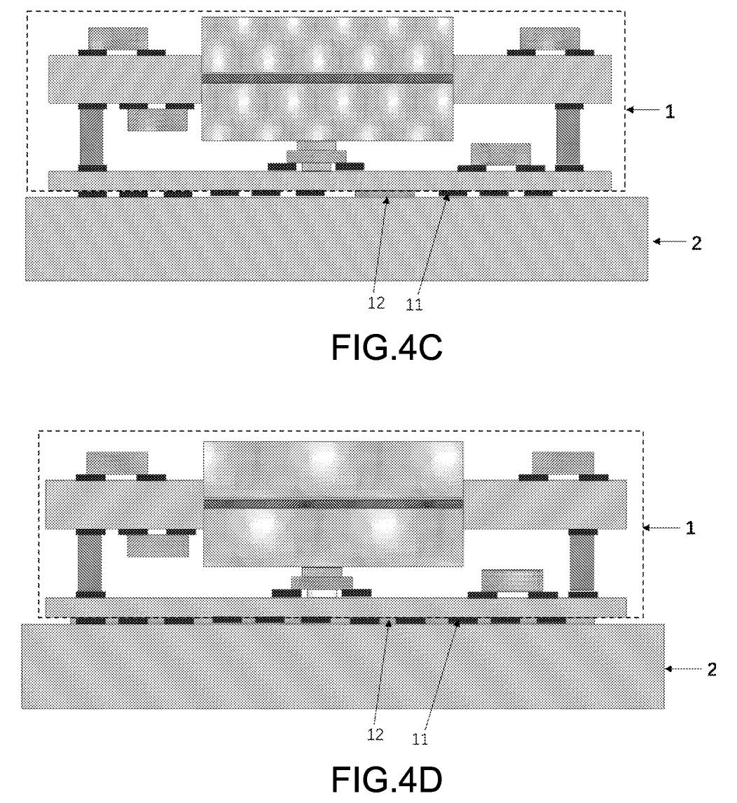

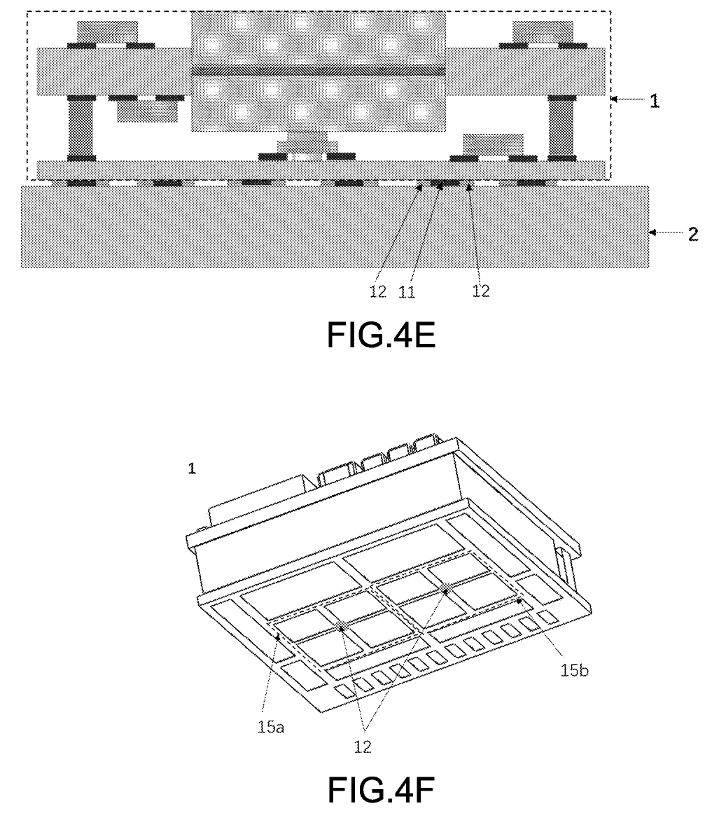

As shown in FIG. 4A and FIG. 4B, the stacked module 1 shown in the present application needs to be assembled on the system board 2 to supply power to the semiconductor chip provided on the system board 2. Similarly, the stacked module 1 and the system board 2 are fixed and electrically connected by means of solder, and fixation between the two is achieved by providing the bonding material.

In detail, for different pin layouts on the lower surface of the stacked module, arrangement manners of the bonding material is shown in FIG. 4C to FIG. 4F. FIG. 4C shows a fixing manner between the stacked module and the system board, the solder is provided on the pad of the system board, and the bonding material is provided at a position outside the pad, the bonding material 12 is not in contact with the pad and the solder 11, and then the stacked module is attached to the system board 2, and after reflow soldering, the soldering of the solder and the curing of the bonding material are completed, thereby realizing the electrical connection and fixation between the stacked module and the system board. When other elements are mounted on the other surface of the system board, and reflow soldering is performed again, the cured bonding material can ensure that the module will not shift or fall, thereby ensuring the reliability and yield of production.

FIG. 4D shows another fixing manner between the stacked module and the system board. In this embodiment, the bonding material 12 fills the gap between the solder on the pads and wraps the surface of the solder, and then the stacked module is attached to the system board 2. After reflow soldering, the soldering of the solder and the curing of the bonding material are completed, and the same technical effect described above can also be achieved. Preferably, the bonding material may also have a soldering-assisting function, thereby further improving the reliability of welding. Manners of implementation may be: 1. the solder is disposed on the pad of the system board, and then the bonding material is disposed on the surface or an adjacent area of the solder; and 2, when a BGA or a LGA is used for the connection between the stacked module and the system board, the bonding material can be provided on the surface or the adjacent area of the solder after the solder is pre-deposited on the surface of the stacked module and/or the system board.

FIG. 4E shows another fixing manner between the stacked module and the system board. In this embodiment, the bonding material 12 does not fill the gap between the solder, but is coated on the surface of the solder. A manner of implementation may be doping the bonding material 12 within the solder, and then the doped solder being disposed on the pad of the system board. During the reflow soldering process, after the solder melts and coalesces, the bonding material is expelled from the solder, thereby achieving the effect of the bonding material wrapping around the solder.

After the bonding material in the above embodiments is cured, when the solder is subjected to reflow soldering again, no shifting or dropping occurs between the stacked module and the system board. Preferably, the bonding material may also have a soldering-assisting function, thereby further improving the reliability of welding.

FIG. 4F shows a pad layout of the lower surface of the stacked module 1, the pad on the lower surface of the stacked module 1comprising a first co-potential pad region 15a and a second co-potential pad region 15b, and in order to avoid the influence of the bonding material on the solder joints as much as possible, the bonding material 12 may be disposed among the pads with same potential; in addition, during assembly process, the bonding material 12 can be directly arranged on the system board 2 provided with solder, and then the stacked module and the system board are attached, and then performing reflow soldering.

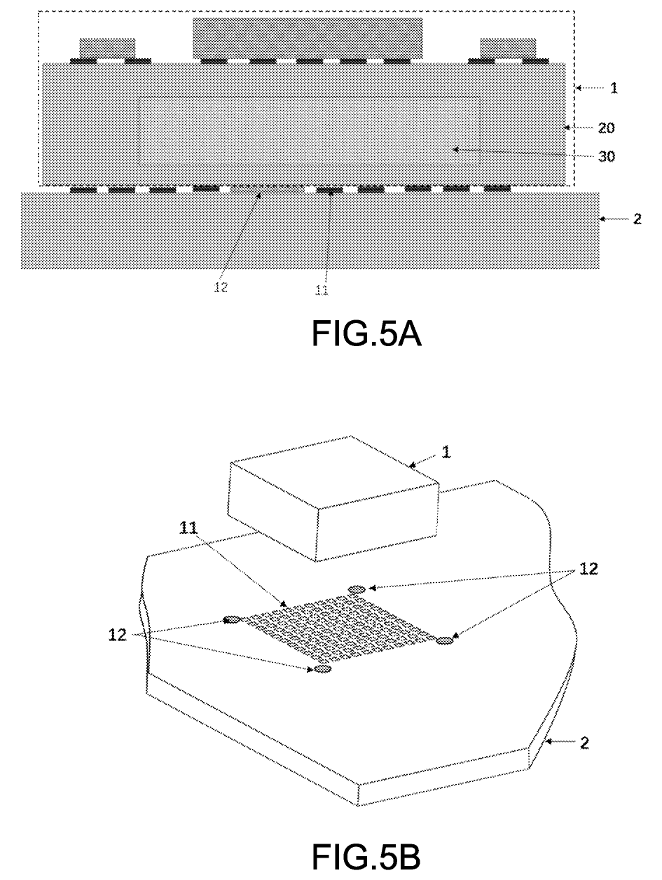

FIG. 5A is another implementation of the stacked module 1, and a fixing manner between the stacked module 1 and the system board 2. In the present embodiment, the stacked module 1 comprises a first substrate 10 and an element 30, wherein the element 30 is embedded in the first substrate 10; the first substrate 10 comprises an upper surface and a lower surface opposite to each other, the upper surface of the first substrate 10 may be provided with other elements, and the lower surface of the first substrate 10 is provided with a pad fixed and electrically connected to the system board; the bonding material 12 is arranged between the lower surface of the first substrate 10 and the upper surface of the system board 2, and the same technical effect can be obtained by using the aforementioned embodiments.

FIG. 5B is another fixing manner between the stacked module 1 and the system board 2. In this embodiment, the stacked module 1 may be any one of the stacked modules in the aforementioned embodiments, but is not limited thereto. The upper surface of the system board 2 is provided with the pad and the solder 11 , and the bonding material 12, wherein the bonding material 12 is provided around the combination of the pad and the solder 11, such as four corners of the combination of the pad and the solder 11; further, the four positions for the bonding material 12 are in one-to-one correspondence with positions of four corners of the stacked module 1. The stacked module and the system board aforementioned can also adopt the position of the bonding material in this embodiment, and the same technical effect can be obtained.

The thickness of the stacked power module of the above embodiments is greater than or equal to 5 mm. The stacked power module of the above embodiments can also be a part of the electronic device, which can satisfy the technical features and benefits disclosed in the present application.

The " equal " or " same " or " equal to " disclosed by the application needs to consider the parameter distribution of engineering, and the error distribution is within +/-30%; and the included angle between the two line segments or the two straight lines is less than or equal to 45 degrees; the included angle between the two line segments or the two straight lines is within the range of [ 60, 120 ]; and the definition of the phase error phase also needs to consider the parameter distribution of the engineering, and the error distribution of the phase error degree is within +/-30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A power module, comprising a substrate, an element, a solder and a bonding material, wherein the element and the substrate are stacked; the substrate and the element are fixed and electrically connected by means of the solder;
The bonding material is further provided between the substrate and the element, and the substrate and the element are fixed by means of the bonding material;
The moment when the bonding material is fully cured is later than the moment when the solder begins to melt.

2. The power module of claim 1, wherein a thickness of the power module is greater than or equal to 5 mm.

3. The power module of claim 1, wherein the substrate is a first substrate, the element is a magnetic core, and the power module further comprises a second substrate; the magnetic core is assembled on the second substrate; each of the first substrate and the magnetic core comprises an upper surface and a lower surface opposite to each other, and the upper surface of the first substrate and the lower surface of the magnetic core are fixed by means of the bonding material.

4. The power module of claim 1, wherein the substrate is a first substrate, and the power module further comprises a second substrate; the first substrate, the element, and the second substrate are sequentially stacked; each of the first substrate, the element and the second substrate comprises an upper surface and a lower surface opposite to each other, and the upper surface of the first substrate and the lower surface of the element are fixed by means of the bonding material; the upper surface of the element and the lower surface of the second substrate are fixed by means of the bonding material.

5. The power module of claim 1, wherein the power module further comprises an additional element, each of the element and the substrate comprises an upper surface and a lower surface opposite to each other, and the lower surface of the element and the upper surface of the substrate are adjacent to each other;
the additional element is disposed on the upper surface of the substrate; the substrate is fixed on and connected to the element by means of the bonding material disposed between an upper surface of the additional element and the lower surface of the element.

6. The power module of claim 5, wherein the additional element is mounted to the substrate by a fixing material.

7. The power module of claim 6, wherein a lower surface of the additional element is provided with a pad, and the additional element is fixed on and electrically connected to the substrate by means of the pad and the solder; the upper surface and/or the lower surface of the additional element are provided with a surface treatment area, and the surface treatment area is used for preventing the bonding material or the fixing material from flowing into the pad.

8. The power module of claim 1, wherein the power module is disposed on a system board, and the power module and the system board are fixed by means of the solder and the bonding material, and electrically connected through the solder.

9. The power module of claim 8, wherein there is a gap between the bonding material and the solder provided between the power module and the system board.

10. The power module of claim 8, wherein the bonding material between the power module and the system board fills a gap between the solder, and the bonding material between the power module and the system board wraps around the solder.

11. The power module of claim 8, wherein a lower surface of the power module is provided with a pad region, and the bonding material is disposed around the pad region.

12. The power module of claim 8, wherein the bonding material between the power module and the system board is wrapped around the solder; and a gap exists between the adjacent bonding materials wrapped the solder.

13. The power module of claim 8, wherein a lower surface of the power module is provided with a pad, the pad comprises a co-potential pad region, and the bonding material is disposed in the co-potential pad region.

14. The power module of claim 1, wherein the substrate comprises a pad; the bonding material is doped within the solder, and the solder with doped bonding material is disposed on the pad; or the solder is disposed on the substrate first, and then the bonding material is disposed on the surface of the solder.

15. A power module, comprising an element, a substrate, a solder and a bonding material, the element being disposed on the substrate; the power module is arranged on a system board, the solder and the bonding material are disposed between the substrate and the system board, the substrate is fixed and electrically connected to the system board by means of the solder, and the substrate and the system board are fixed by means of the bonding material; and the moment when the bonding material is fully cured is later than the moment when the solder starts to melt.

16. The power module of claim 15, wherein the element is embedded in the substrate.

17. The power module of claim 15, wherein the substrate comprises an upper surface and a lower surface, the lower surface of the substrate is provided with a pad region, and the bonding material is disposed around the pad region.

18. An assembly method of the power module of claim 1, comprising the following steps:
step 1: first disposing the solder and the bonding material on the substrate;
step 2: attaching the element to the substrate;
step 3: performing reflow soldering on an attached combination in step 2 to complete solder welding and curing of the bonding material; and in step 3, the moment at which the bonding material is fully cured is later than the moment at which the solder starts to melt.

19. The assembly method of claim 18, wherein the substrate is a first substrate, the power module further comprises a second substrate, the element is a magnetic core, and the step 1 further comprises: assembling the magnetic core on the second substrate; and attaching other elements on an upper surface of the first substrate, and/or an upper surface and/or a lower surface of the second substrate.

20. The assembly method of claim 18, wherein the substrate is a first substrate, the power module further comprises a second substrate, and the assembly method further comprises:
step 4: disposing the solder and the bonding material on the second substrate, and attaching the attached combination completed in step 3 with the second substrate;
step 5: performing reflow soldering on the attached combination completed in step 4, and completing solder welding and curing of the bonding material.

21. The assembly method of claim 18, wherein further comprises a solder with doped bonding material, and the solder with doped bonding material is disposed on the pad; or the solder is disposed on the substrate first, and then the bonding material is disposed on the surface of the solder.
